(19) United States
(12) Patent Application Publication
(10) Pub. No.: US 2010/0140616 A1
(43) Pub. Date: Jun. 10, 2010

(54) Electronic device and method for manufacturing the same

(75) Inventor: Daiki Kaya, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/453,051

(22) Filed: Apr. 28, 2009

(30) Foreign Application Priority Data
Dec. 5, 2008 (JP) 124802/2008

(51) Int. Cl. H01L 23/00; H01L 21/28

(52) U.S. Cl. 257/48; 438/597; 257/E23.002; 257/E21.158

(57) ABSTRACT

Disclosed herewith is an electronic device capable of preventing the surfaces of the analyzing terminals from such external factors as oxidation, etc. so as to improve the accuracy of the analysis of the electronic device. The electronic device has plural signal lines and is to be mounted on a wiring substrate. The electronic device also includes plural lead terminals connected to the signal lines electrically and to be mounted on the wiring substrate, as well as analyzing terminals connected electrically to the signal lines and to be connected to an analyzing device upon analyzing the electronic device respectively and a protective member with insulating performance, which covers at least one of the analyzing terminals 1 and can be removed upon analyzing. The protective member is made of, for example, resin and it is removed when the electronic device is to be analyzed.

### FIELD OF THE INVENTION

The present invention relates to an electronic device such as a semiconductor device, etc. and its manufacturing method and more particularly to an electronic device having a package of which analysis performance is improved, as well as its manufacturing method.

### BACKGROUND OF THE INVENTION

Electronic devices such as semiconductor devices, etc. have electrode pads and lead terminals that output signals from those electrode pads to external respectively. Those pads and terminals are formed on their semiconductor chips, respectively. In each of such electronic devices, the lead terminals are formed on a wiring substrate. Therefore, when the electronic device is removed from the wiring substrate so as to be analyzed, the device is often damaged, thereby the analysis is disabled. And in order to prevent such troubles, some of those electronic devices have analyzing terminals that are not mounted on their wiring substrates while the lead terminals are formed on the wiring substrates. Each of those electronic devices except for its lead and analyzing terminals is covered by a package made of sealing resin or the like (e.g., JP-A No. Hei11(1999)-163211).

When carrying out an inspection and/or a performance evaluation of an electronic device and its wiring substrate on which the electronic device is to be mounted, the test pin of the subject analyzing device is connected to the inspection terminal of the electronic device. Then, a current is flown to the electronic device or its wiring substrate through the inspection terminal to carry out the performance evaluation and/or inspection.

### SUMMARY OF THE INVENTION

In case of such conventional electronic devices, the analyzing terminal of each electronic device is formed so that its surface that comes in contact with the subject analyzing device is kept exposed. Thus the contact surface is often damaged by oxidation and foreign matters to be stuck thereon, thereby the analysis is disabled. This has been a problem for those conventional electronic devices.

Under such circumstances, according to one aspect of the present invention, the electronic device includes plural signal lines and it is to be mounted on a wiring substrate. The electronic device also includes plural lead terminals connected to the signal lines and formed on the wiring substrate, as well as plural analyzing terminals connected to the signal lines and to be connected to the object analyzing device upon analyzing the electronic device, and a protective member with insulating performance, which covers at least one of the analyzing terminals and is removable upon carrying out the analysis.

According to another aspect of the present invention relating to the electronic device, the surface of the each analyzing terminal is protected by a removable protective member and the protective member is removed upon carrying out an analysis, thereby preventing analysis failures that might otherwise occur due to such external factors as analyzing terminal surface oxidation, etc. so as to improve the accuracy of the analysis of the electronic device.

As a result, the electronic device of the present invention can prevent analysis failures to be caused by such external factors as analyzing terminal surface oxidation, etc. so as to improve the accuracy of the analysis.

### BRIEF DESCRIPTION OF THE DRAWINGS

FIG. 1 is a top view of an electronic device in a configuration employed in a first embodiment of the present invention;

FIG. 2 is a cross sectional view taken on a line of FIG. 1; and

FIG. 3 is a top view of an electronic device in a configuration employed in a second embodiment of the present invention.

### DETAILED DESCRIPTION OF THE PREFERRED EMBODIMENTS

Hereunder, there will be described the preferred embodiments of the present invention with reference to the accompanying drawings.

### First Embodiment

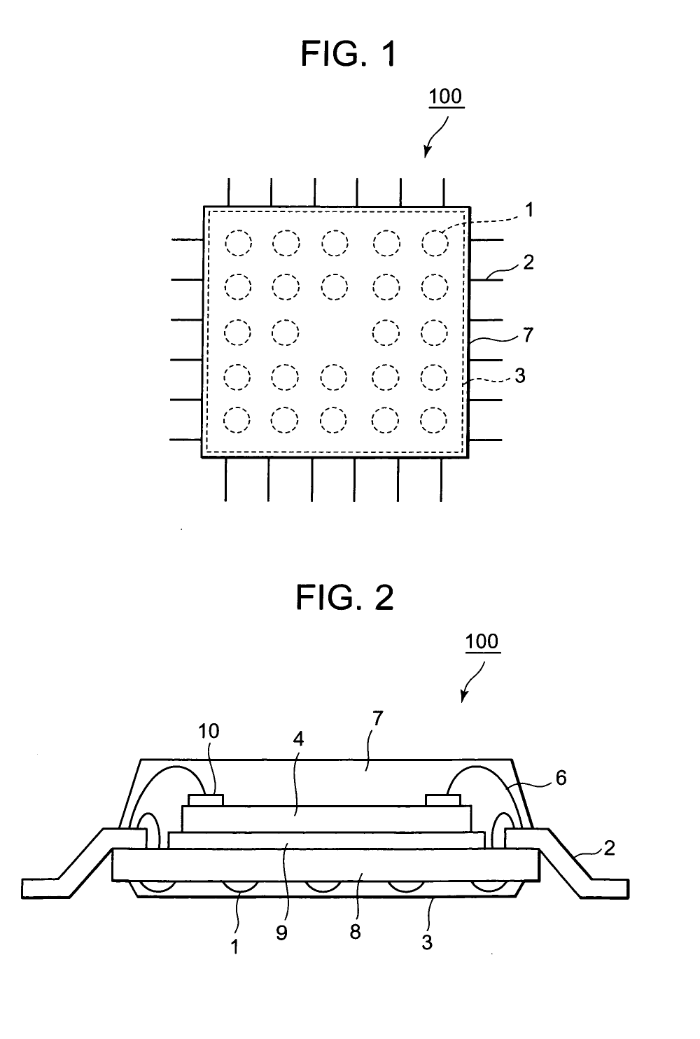

FIG. 1 is a top view of an electronic device in a configuration employed in the first embodiment of the present invention and FIG. 2 is a cross sectional view taken on a line of FIG. 1. This electronic device 100 includes plural signal lines and is to be mounted on a wiring substrate (not shown). The electronic device 100 also includes plural lead terminals 2 connected to the signal lines and mounted on the wiring substrate respectively, plural analyzing terminals 1 connected to the signal lines and to a subject analyzing device upon carrying out the analysis of the electronic device, and a removable protective member with insulating performance 3, which covers at least one of the analyzing terminals 1.

The electronic device 100 is formed in a rectangular shape and covered entirely by sealing resin 7. At the four side faces of the electronic device 100 are formed plural needle-like lead terminals 2 so as to be protruded outside. Those lead terminals 2 are separated from one another at predetermined intervals. The total number of those lead terminals 2 formed at the four sides is, for example, 256 or so. However, most of the lead terminals are omitted here to simplify the description. The lower surface of the electronic device 100 in FIG. 1 is mounted on the external wiring substrate. Plural analyzing terminals 1 are formed and disposed on this mounting surface in a matrix pattern. The analyzing terminals 1 and the lead terminals 2 are disposed on one-to-one correspondence. In other words, if the total number of the lead terminals 2 is 256, the total number of the analyzing terminals is also 256. Most of the analyzing terminals 1 are omitted here to simplify the description.

Each analyzing terminal 1 inputs/outputs the same signals as those of its corresponding lead terminal 2. Consequently, all the input and output signals of the electronic device 100 can be outputted to the external analyzing device through those analyzing terminals 1. The analyzing terminals 1 and the lead terminals 2 do not necessarily have a one-to-one correspondence with each other, and the electronic device may be provided only with the terminals used to input/output analysis signals.

As shown in FIG. 2, the electronic device 100 has a substrate 8 inside the sealing resin 7. On the internal substrate 8 is disposed a die-pad 9. The die-pad 9 is formed so as to fasten the semiconductor chip 4 to the internal substrate 8 and radiate the heat generated from the semiconductor chip 4. The semiconductor chip 4 has an electronic circuit (not shown) in which plural wirings are formed. Those wirings are connected to an electrode pad 10 formed on the surface of the semiconductor chip 4.

One ends of the lead terminals 2 are formed on the surface of the internal substrate 8 and the other ends thereof are formed so as to be extended outside the sealing resin 7. The one ends of the lead terminals 2 formed on the surface of the internal substrate 8 are connected to the electrode pad 10 through wires 6. This means that the lead terminals 2 are connected electrically to the signal lines formed on the semiconductor chip 4 through the electrode pad 10. The other ends of the lead terminals 2 extended outside the sealing resin 7 are, for example, soldered to the outside wiring substrate (not shown). Consequently, signals outputted from the externally formed electronic circuit are outputted to the outside wiring substrate through the electrode pad 10 and through the lead terminals 2, then inputted to the internal electronic circuit through the lead terminals 2 and through the electrode pad 10.

The surfaces of the analyzing terminals 1 are formed spherically and the spherical surfaces are extruded outside. The test pin of the analyzing device connected to the object analyzing terminal 1 has a spherical hole at its tip so as to be engaged with this spherical surface. The test pin having such a spherical hole is engaged with the spherical surface of the object analyzing terminal 1 to make a contact area between the analyzing terminal 1 and the test pin. As described above, the lead terminals 2 and the analyzing terminals 1 have a one-to-one correspondence with each other. The analyzing terminals 1 are connected to their corresponding lead terminals 2 through the wires 6 respectively. This means that the paired analyzing terminal 1 and lead terminal 2 are connected to the same signal line electrically.

The electronic device 100 except for the end portions of the lead terminals 2 mounted on the wiring substrate and the analyzing terminals 1 is covered by the sealing resin 7. On the mounting surface of the electronic device 100 is formed a protective member 3 that covers all the analyzing terminals 1. The protective member 3 is made of an insulating material. The material of the protective member 3 is, for example, resin. The protective member 3 protects the surfaces of the analyzing terminals from oxidation and sticking of foreign matters. Although only one protective member 3 is used to cover all the analyzing terminals 1 in FIGS. 1 and 2, the protective member 3 may be formed for each of those analyzing terminals 1.

The electronic device 100 configured as described above is mounted on a wiring substrate while its analyzing terminals 1 are covered by the protective member 3. Although the lead terminals 2 are mounted on the wiring substrate, the analyzing terminals 1 are not mounted on the wiring substrate. When analyzing the electronic device 100, the electronic device 100 is removed from the wiring substrate. And the protective member 3 formed on the electronic device 100 is dissolved by a solvent. Because the protective member 3 is removed in such a way, the analyzing terminals 1 come to be exposed. As a result, the test pin of the analyzing device can be put in contact with the object analyzing terminal 1. Then, analysis signals are inputted to the electronic device 100 from the test pin of the analyzing device and the analyzing device analyzes the signals outputted from the electronic device 100 through the analyzing terminal 1. The analysis of the electronic device 100 can also be carried out before the electronic device 100 is mounted on the wiring substrate. Furthermore, when mounting the electronic device 100 on the wiring substrate again after the analysis, the protective member 3 can be formed again to mount the electronic device 100 on the wiring substrate.

In the electronic device 100 configured as described above, because the analyzing terminals 1 are protected by the protective member 3, the electronic device 100 can prevent analysis failures that might otherwise occur due to such external factors as surface oxidation, foreign matters stuck on the surface. Furthermore, the electronic device 100 can be prevented from being mounted on the wiring substrate by mistake. And upon analyzing the electronic device 100, the protective member 3 is removed to expose the object analyzing terminal 1. And because the analyzing terminal 1 is protected by the protective member 3 in such a way, the surface of the analyzing terminal 1 can be kept properly until the analysis is carried out. Consequently, the accuracy of the analysis is improved.

Although the analyzing terminals 1 are formed on the mounting surface of the internal substrate as described above, the terminals 1 may also be formed on the opposite surface of the mounting surface. If the analyzing terminals 1 are formed on the top surface, the analyzing terminals 1 may be used to analyze the electronic device 100 without removing the electronic device 100 from the internal substrate 8.

### Second Embodiment

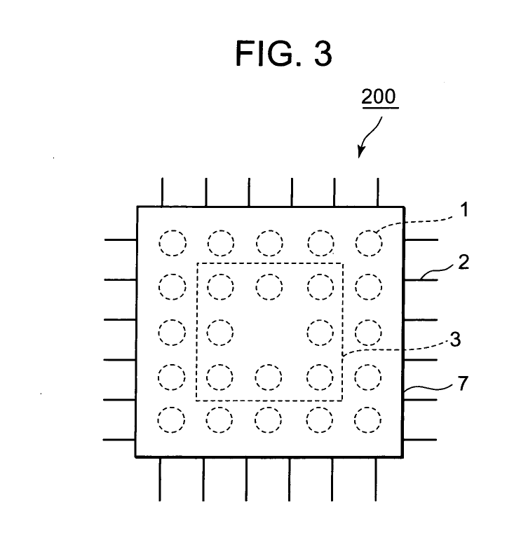

FIG. 3 is a top view of an electronic device in a configuration employed in this second embodiment of the present invention. The electronic device 200 in this second embodiment is characterized in that the protective member 3 covers some of plural analyzing terminals 1. The analyzing terminals 1 correspond to the lead terminals 2 respectively. However, all the analyzing terminals 1 are not used for analyzing. Consequently, the protective member 3 is formed so as to cover only the analyzing terminal 1 used for analyzing. The protective member 3 does not cover other analyzing terminals 1 that are not used for analyzing. As a result, the surface of the analyzing terminal 1 used for analyzing is prevented from oxidation until the analysis is carried out, thereby the area of the protective member 3 can be reduced.

The present invention is not limited only for the embodiments described above, and it is to be understood that modifications will be apparent to those skilled in the art without departing from the spirit of the invention.

What is claimed is:

1. An electronic device having a plurality of signal lines and to be mounted on a wiring substrate, comprising:
a plurality of lead terminals electrically connected to the signal lines and to be mounted on the wiring substrate;
a plurality of analyzing terminals electrically connected to the signal lines and to be connected to an analyzing device upon analyzing the electrical device; and
a protective member having insulating performance, which covers at least one of the analyzing terminals and being removable upon analyzing the electronic device.

2. The electronic device according to claim 1, wherein the protective member is resin.

3. The electronic device according to claim 1, wherein the analyzing terminals and the lead terminals have a one-to-one correspondence with each other.

4. The electronic device according to claim 1,
wherein the lead terminals are connected to electrode pads that input/output the signals to/from the signal lines respectively; and
wherein the analyzing terminals are connected to the lead terminals, respectively.

5. The electronic device according to claim 1, wherein the analyzing terminals are formed on a mounting surface of the wiring substrate or its opposite surface.

6. A method for manufacturing an electronic device having a plurality of signal lines and to be mounted on a printed board, the method comprising:
forming an inspection terminal with conductivity, which is connected to the signal lines and formed on a surface of the electronic device; and
covering at least one of the analyzing terminals with a protective member having insulating performance.

7. The method according to claim 6, further comprising:
removing the protective member to analyze the electronic device.

8. The method according to claim 7, further comprising:
dissolving and removing the protective member with a solvent.

9. The method according to claim 6, wherein the protective member is resin.
